(19) United States
(12) Patent Application Publication
(10) Pub. No.: US 2021/0410328 A1
(43) Pub. Date: Dec. 30, 2021

(54) COLD PLATE WITH PROTECTIVE MATERIAL TO PREVENT REACTION WITH LIQUID COOLANT

(71) Applicant: Intel Corporation, Santa Clara, CA (US)

(72) Inventors: Jin YANG, Hillsboro, OR (US); David SHIA, Portland, OR (US); Mohanraj PRABHUGOUD, Hillsboro, OR (US)

(21) Appl. No.: 17/473,896

(22) Filed: Sep. 13, 2021

(51) Int. Cl. H05K 7/20

(52) U.S. Cl. CPC H05K 7/20254; H05K 7/20781

(57) ABSTRACT

An apparatus is described. The apparatus includes a cold plate having fluidic channels within the cold plate. The fluidic channels have protective material thereon such that when liquid coolant flows through the fluidic channels the protective material is between the liquid coolant and the cold plate's material, wherein, the protective material is to prevent reaction between the liquid coolant and the cold plate's material.

### BACKGROUND

The total power consumption of computing and/or networking systems continues to scale upward with the increasing performance of these systems. A significant component of a system's total power consumption is the power consumption of any/all of its high performance semiconductor chips(s) and/or electro-optic devices. Because the heat generated by an electronic device increases with its power consumption, systems designers are increasingly presented with thermal related hurdles and designing their systems to overcome them.

### FIGURES

A better understanding of the present invention can be obtained from the following detailed description in conjunction with the following drawings, in which:

FIG. 1 shows a data center with liquid cooled electronic systems;

FIG. 2 shows cold plates mounted on packages;

FIGS. 3a and 3b show a prior art cold plate;

FIGS. 4a and 4b show an improved cold plate;

FIG. 5 shows a process for making an improved cold plate;

FIG. 6 shows a cooling system;

FIG. 7 shows a system;

FIG. 8 shows a data center;

FIG. 9 shows a rack.

### DESCRIPTION

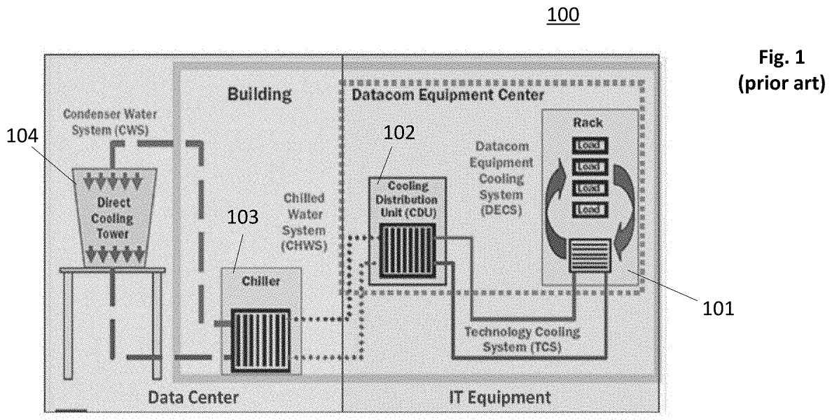

FIG. 1 shows a high-level depiction of a high performance computing environment 100, such as a centralized data center or cloud service nerve center, that includes liquid cooling. As observed in FIG. 1, multiple racks 101 each containing shelves of computing and/or networking equipment are located in a confined area. Generally, information system (IS) managers desire to pack large amounts of computing performance into small areas. Likewise, semiconductor chip manufacturers and computing equipment manufacturers attempt to densely integrate high performance functionality into their respective products.

As the performance of semiconductor chips (and the computing/networking systems that the chips are integrated into) continues to increase, however, so does their associated power consumption. Unfortunately, the performance of many semiconductor chips and computing/networking system products has crossed a threshold at which traditional air-cooling is unable to keep the chips/equipment sufficiently cool.

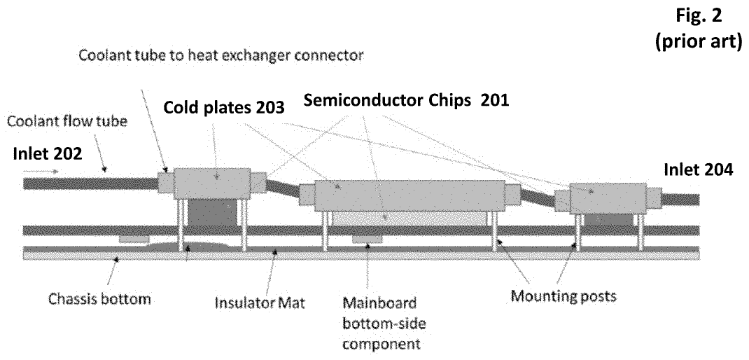

As such, liquid cooling solutions are steadily being integrated into today's computing/networking systems. Here, as observed in FIG. 2, a computing system or networking system (“system”), such as a blade server, a disaggregated computing system CPU unit, a switching hub, etc., includes a number of packaged semiconductor chips 201. The system also includes an inlet 202 to receive cooled fluid. Cold plates 203 are mechanically coupled to the various packaged semiconductor chips 201 within the system and the cooled fluid is routed, e.g., by way of one or more manifolds and conduit tubing, through the cold plates 203.

As the semiconductor chips 201 operate they transfer heat to their respective cold plates 203, which, in turn, transfers the heat to fluid that runs through the cold plates 203 (there is no direct contact of the coolant to the electronic devices). The warmed fluid is then collected through one or more manifolds and tubing and routed to a warmed fluid outlet port 204. Note that although FIG. 2 depicts cold plates attached to the semiconductor chips 201, other liquid cooling solutions attach heat exchangers to the semiconductor chips 201. Both cold plates and heat exchangers have fluid input/output junctions as depicted.

The simple running of cooled liquid into a cold plate and warmed liquid out of a cold plate is referred to as “single-phase” cooling. That is, the coolant (with a relatively high boiling point, e.g., above 100° C.) enters the cold plate as a liquid, remains a liquid within the cold plate, and then ultimately exits the cold plate as a liquid.

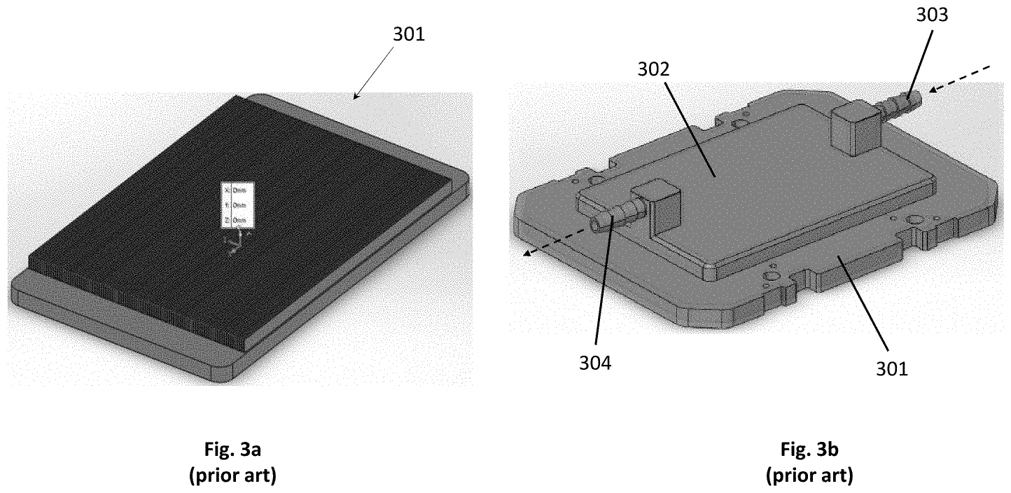

FIG. 3a shows a top down view of the internal structure of a prior art cold plate. As can be observed in FIG. 3a, the inside of a cold plate is composed of long, thin fluidic channels. The cold plate is formed, e.g., from a copper base plate 301 having fins that protrude upward from the base plate's surface. The spaces between fins, in turn, form the base plate's fluidic channels. In various approaches, a first mass block of copper is machined/milled (e.g., skived) to form the fins. Similarly, referring to FIG. 3b, another mass block of copped is machined/milled to form the cover 302.

The cover 302 is placed over the base plate 301 to enclose the fluid channels and form the completed cold plate. In various approaches, high temperature process are used to seal the base 301 and cover 302 to one another (e.g., brazing, friction stir welding (FSW)).

When put in use, the cold plate is placed on the package of one or more semiconductor chips. A cold fluid tube is connected to the cold plate's fluidic inlet port and a warm fluid tube is connected to the cold plate's fluidic output port. Fluid is pumped through the cold plate's fluidic channels. As the fluid passes through the channels it receives heat that has been transferred to the cold plate from the operating semiconductor chips.

Unfortunately, the coolant chemically reacts with the cold plate components 301, 302. That is, at least in implementations where the cover 302 and/or base plate 301 are composed of copper and the coolant is composed at least partially of oxygen (such as any coolant that includes water (H₂O)), the coolant chemically reacts with the copper in a way that causes the copper to oxidize or otherwise tarnish.

Importantly, the copper surfaces of the cold plate's internal fluidic channels begin to oxidize or tarnish which degrades the performance and/or reliability of the cold plate (for example by reducing the cold plate's cooling efficiency). Passivating the copper surfaces does not suitably prevent the oxidation/tarnish.

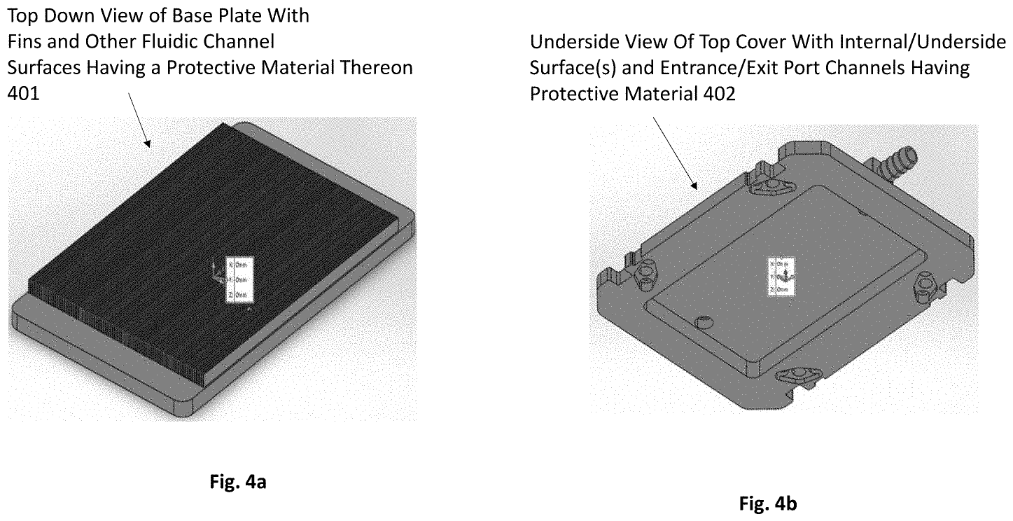

A solution, observed in FIGS. 4a and 4b, is to plate the surfaces of the fluidic channels within the cold plate components 401, 402 with a protective material such as Nickel (Ni). Here, Ni easily plates to copper and is relatively inert such that it will not react with the coolant. The protective material prevents the copper fluidic channel surfaces within the cold plate components 401, 402 from making contact with the coolant (they are covered by the plated protective material). As such, the copper components 401, 402 are less prone to corrode/tarnish. Likewise, the cold plate's cooling efficiency is less prone to degrade.

According to an embodiment, the copper base plate 401 and the copper cover 402 are individually plated (electro-plating or electroless plating can be used depending on implementation).

For example, both the copper base plate 401 and the copper cover 402 are separately plated in a plating bath that individually plates both components with Ni. The Ni plating at least covers the surfaces of the copper components 401, 402 that form the cold plate's internal fluidic channels. The Ni plating can additionally cover other areas, such as outer surfaces of the copper components 401, 402. For example, both the copper base plate 401 and the copper cover 402 could be entirely covered with Ni.

After the copper base plate 401 and copper cover 402 are plated with the protective material they are attached to one another. A challenge, however, involves the high temperatures used to seal the cover 402 and base plate 401 together to form the finished cold plate. For example, during nominal brazing or welding, temperatures of 800° Celsius (C.) or higher up to 900° C. are applied to either or both of the base plate 401 and cover 402. Temperatures above 750° C. can cause Ni plating to delaminate from a copper surface. If such delamination were to occur, copper fluidic channel surfaces within the cold plate would come in contact with the coolant and defeat the purpose of the Ni plating (the exposed copper surfaces would corrode/tarnish).

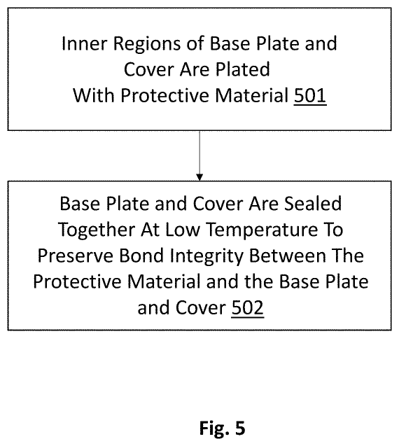

As such, as observed in FIG. 5, after the base plate and cover are individually plated 501 with the protective material, they are sealed together with a low temperature sealing 502 process that preserves the integrity of the bond between the plated protective material and the surfaces of the base plate and cover components.

For example, in the case where Ni is plated to a copper base plate 401 and a copper cover 402 as described above, a brazing process that seals the cover 402 to the base plate 401 is performed at a temperature that remains beneath 750° C. (e.g., within a range of 700° C. to 750° C. inclusive).

Brazing, as is known in the art, incorporates a material having lower melting point (bonding material) between two materials having higher melting point. Possible bonding materials for brazing two, e.g., copper, cold plate components for glycol/water-based coolants include various phosphorous copper (CuP) materials (e.g., BCuP-2, BCuP-3, BCuP-4, to BCuP-5). Heat is then applied to the combined structure that exceeds the melting point of the bonding material but remains beneath the melting point of the outer, higher melting point materials. The bonding material melts in response to the heat while the outer, higher melting point materials remain substantially in a solid phase. The melted bonding material seals to both outer materials (e.g., during cooling) thereby sealing the entire structure together (the outer materials are affectively sealed to one another via the reflowed bonding material).

Here, by keeping the maximum temperature applied during the brazing process at or below 750° C., the Ni protective layer should remain attached to the copper base plate 401 and the copper cover 402. Notably, the bonding material should have a melting point below 750° C. so that is melts in accordance with the brazing technique at the lesser applied temperature. Moreover, in various embodiments a solder is used as the bonding material and the base plate 401 and cover 402 are soldered together (solder, such as tin (Sn) and lead (Pb) based solder, typically has a melting point around 300° C.).

Generally, the base plate 401 and cover 402 attachment process is characterized by: 1) an applied maximum temperature that is less than a temperature at which the protective material will delaminate from the cold plate components 401, 402; and, 2) a bonding material having a melting point temperature that is less than the applied maximum temperature of 1) above. For ease of discussion the remainder of the document will refer to brazing as the attachment process.

In further embodiments, the brazing process is performed within an inert ambient such as an N₂ ambient. Here, by performing the brazing in a non-reactive atmosphere, reactions between the ambient and the bonding material and/or the protective material is avoided. Such reactions, if they were to occur (e.g., as promoted by the application of the brazing heat), could alter the compositions and/or processes at play and detrimentally affect the bonding between the bonding material and the protective material.

Although Ni has been described as the protective material in the above examples, other materials that do not appreciably react with water based coolants can be used as a protective material for copper cold plate components (e.g., rethane finish or sealant and epoxy coating).

Moreover, although plating has been described in the examples above as the process by which the protective material is attached to the cold plate components 401, 402, in other embodiments other processes may be used. Plating is understood to be just one form of deposition (during deposition, a material is deposited on another material). Other forms of deposition can therefore be used to form the protective material on the cold plate components (e.g., plasma deposition, vapor deposition, etc.).

Furthermore, although copper has been described in the examples above as the basic material for the base plate 401 and the cover 402, other thermally conductive materials, such as metals, can be used (e.g., aluminum). Such other materials can use whatever protective material can be deposited on them. For example, in the case of a base plate 401 and cover 402 made of aluminum, a sealant or epoxy can be used as the protective material. Sealants and epoxies are directly applied (coated). As such embodiments exist where the protective material is coated, painted, sprayed, etc. on the base plate components (rather than the deposition processes mentioned above).

Although embodiments above have emphasized single phase liquid cooling in which the coolant remains in a liquid phase as it runs through the cold plate, the teachings above can also apply to cold plates used for “two-phase” cooling. In the case of two-phase cooling, the coolant enters the cold plate as a liquid and then is deliberately evaporated into a vapor. The activity of vaporizing a liquid provides better cooling efficiency as compared to a single-phase approach. After vaporizing the coolant, the coolant exits the cold plate as a vapor (or, is condensed back into a liquid without exiting the cold plate). The cold plate of a two-phase cooling approach is commonly referred to as a “vapor chamber”, however, for ease of description, the term “cold plate” as used herein also includes vapor chamber(s).

Finally, the process of attaching a protective layer to a cold plate component can be applied to immersion cooled systems. In the case of immersion cooled systems, one or more electronic circuit boards with mounted electrical components (e.g., semiconductor chips) are powered on and operating while the boards and their components are immersed in a bath of thermally conducting but electrically insulating liquid.

The complete immersion of the boards and their components maximizes the surface area of the electrical system over which heat from the operating semiconductor chips can be released into the liquid coolant. Heat from the operating semiconductor chips is transferred from the electronic system to the immersion bath. The immersion bath liquid is continually run through a heat exchanger or other component that removes heat from the immersion bath.

In immersion systems, as with both single phase and two phase liquid cooled systems, a heat sink/cold plate is placed in thermal contact with the IHS of the package of one or more semiconductor chips. However, commonly the heat sink/cold plate is a solid mass block. That is, there are no fluidic channels within the block. Rather, the solid mass block absorbs heat from the package IHS which is then transferred directly into the immersion bath (the solid mass block is immersed in the bath and heat is radiated from the outer surface of the block directly into the coolant).

Here, e.g., if the mass block cold plate is composed of copper and the coolant has oxygen, the aforementioned oxidation/corrosion can occur at the outer surface of the mass block cold plate. As such, in another embodiment, the outer surface of the mass block cold plate is covered (e.g., plated, coated, etc.) with a protective material consistent with the teachings above. The protective material prevents the outer surface of the copper block from making contact with the coolant thereby avoiding oxidation/corrosion.

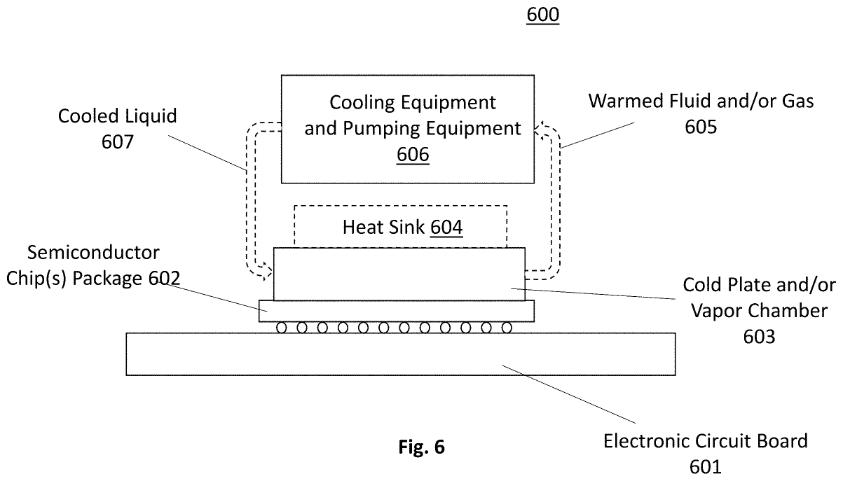

FIG. 6 depicts a general cooling apparatus 600 whose features can be found in many different kinds of semiconductor chip cooling systems. As observed in FIG. 6, one or more semiconductor chips within a package 602 are mounted to an electronic circuit board 601. A cold plate 603 is thermally coupled with the package 602 (e.g., by being placed on the package 602 with a thermally conductive material (“thermal interface material”) between them) so that the cold plate 603 receives heat generated by the one or more semiconductor chips (the cold plate 603 can also be referred to as a vapor chamber in the case of two phase cooling systems).

Liquid coolant is within the cold plate 603. If the system also employs air cooling (optional), a heat sink 604 can be thermally coupled to the cold plate 603. Warmed liquid coolant and/or vapor 605 leaves the cold plate 603 to be cooled by one or more items of cooling equipment (e.g., heat exchanger(s), radiator(s), condenser(s), refrigeration unit(s), etc.) and pumped by one or more items of pumping equipment (e.g., dynamic (e.g., centrifugal), positive displacement (e.g., rotary, reciprocating, etc.)) 606. Cooled liquid 607 then enters the cold plate 603 and the process repeats.

With respect to the cooling equipment and pumping equipment 606, cooling activity can precede pumping activity, pumping activity can precede cooling activity, or multiple stages of one or both of pumping and cooling can be intermixed (e.g., in order of flow: a first cooling stage, a first pumping stage, a second cooling stage, a second pumping stage, etc.) and/or other combinations of cooling activity and pumping activity can take place.

Moreover, the intake of any equipment of the cooling equipment and pumping equipment 606 can be supplied by the cold plate of one semiconductor chip package or the respective cold plate(s) of multiple semiconductor chip packages. In the case of the later (intake received from cold plate(s) of multiple semiconductor chip packages), the semiconductor chip packages can be components on a same electronic circuit board or multiple electronic circuit boards. In the case of the later (multiple electronic circuit boards), the multiple electronic circuit boards can be components of a same electronic system (e.g., different boards in a same server computer) or different electronic systems (e.g., electronic circuit boards from different server computers). In essence, the general depiction of FIG. 6 describes compact cooling systems (e.g., a cooling system contained within a single electronic system), expansive cooling systems (e.g., cooling systems that cool the components of any of a rack, multiple racks, a data center, etc.) and cooling systems in between.

FIG. 6 also describes immersion cooling systems where it is understood that the warmed fluid and/or vapor flow 605 is from the immersion bath chamber (not shown for illustrative ease) and the cooled fluid flow is 607 is into the immersion bath chamber.

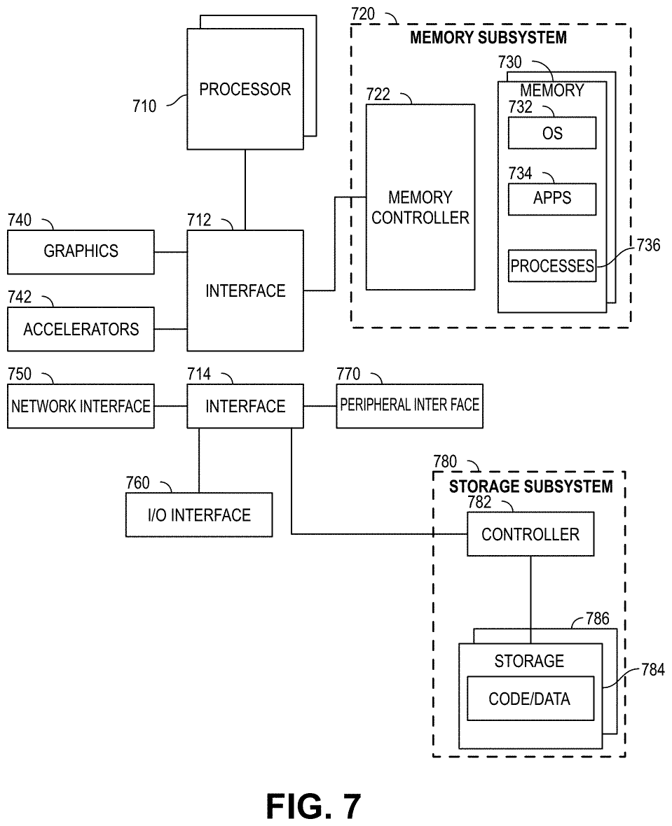

The following discussion concerning FIGS. 7, 8 and 9 are directed to systems, data centers and rack implementations, generally. It is pertinent to point out that any package of any one or more semiconductor chips and/or electro-optics devices within any of these systems, data centers and rack implementations described below can include a colt plate that includes the improvements described above.

FIG. 7 depicts an example system. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include network processors to perform such networking functions (e.g., in a pipelined fashion or otherwise).

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), tensor processors (e.g., neural network processors (NNPs)), “X” processing units (XPUs), programmable control logic, and programmable processing elements such as field programmable gate arrays (FPGAs). Accelerators 742 can provide multiple neural networks, processor cores, or graphics processing units for use by artificial intelligence (Al) or machine learning (ML) models. For example, the Al model can use or include any or a combination of: a reinforcement learning scheme, 0-learning scheme, deep-Q learning, or Asynchronous Advantage Actor-Critic (A3C), combinatorial neural network, recurrent combinatorial neural network, or other Al or ML model. Multiple tensor processors, processor cores, or graphics processing units can be made available for use by Al or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits or logic in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 700. More specifically, power source typically interfaces to one or multiple power supplies in system 700 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

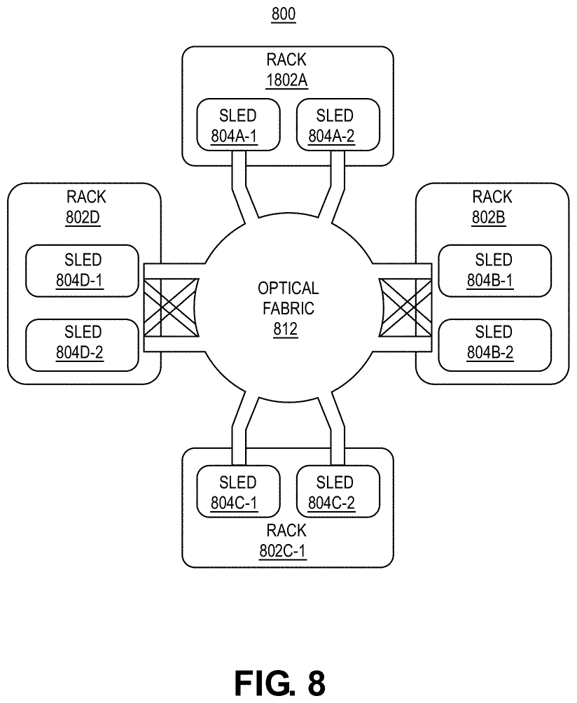

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks.

Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds. Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

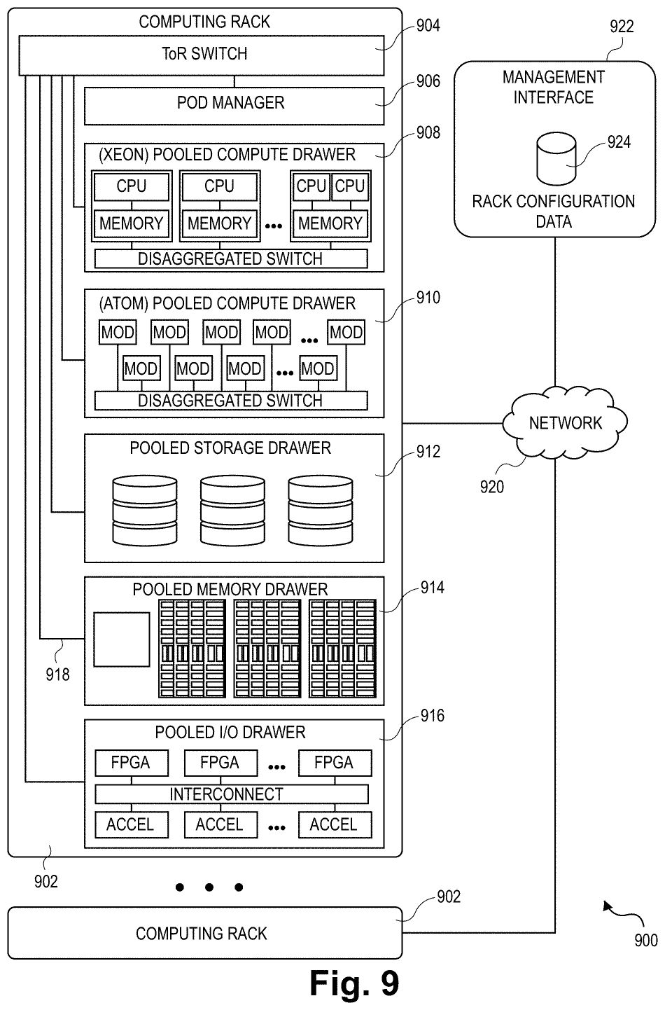

FIG. 9 depicts an environment 900 that includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM™ pooled compute drawer 910, a pooled storage drawer 912, a pooled memory drawer 914, and a pooled I/O drawer 916. Each of the pooled system drawers is connected to ToR switch 904 via a high-speed link 918, such as a 40 Gigabit/second (Gb/s) or 100 Gb/s Ethernet link or an 100+ Gb/s Silicon Photonics (SiPh) optical link. In one embodiment high-speed link 918 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their ToR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations. RSD environment 900 further includes a management interface 922 that is used to manage various aspects of the RSD environment. This includes managing rack configuration, with corresponding parameters stored as rack configuration data 924.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (lCs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. An apparatus, comprising:
a cold plate comprising fluidic channels within the cold plate, the fluidic channels having a protective material thereon such that when a liquid coolant flows through the fluidic channels the protective material is between the liquid coolant and the cold plate's material, wherein, the protective material is to prevent reaction between the liquid coolant and the cold plate's material.

2. The apparatus of claim 1 wherein the cold plate comprises a base and a cover that are brazed together.

3. The apparatus of claim 2 wherein a bonding material between the base and the cover has a melting point temperature that is less than a temperature at which the protective material will delaminate from the cold plate's material.

4. The apparatus of claim 1 wherein the cold plate material comprises copper.

5. The apparatus of claim 4 wherein the protective material comprises nickel.

6. The apparatus of claim 1 wherein the protective material is plated on the cold plate's material.

7. The apparatus of claim 1 wherein the protective material is coated on the cold plate's material.

8. The apparatus of claim 1 wherein the protective material is at least one of:
a sealant;
an epoxy.

9. A data center, comprising:
multiple computing systems mechanically integrated into multiple racks and communicatively coupled to one another by way of at least one network, the data center comprising a cooling system, wherein, at least one of the computing systems comprises a package for a semiconductor chip that includes at least one of a processor and an accelerator, the package in thermal contact with a cold plate comprising fluidic channels within the cold plate, the fluidic channels having a protective material thereon such that when a liquid coolant flows through the fluidic channels the protective material is between the liquid coolant and the cold plate's material, wherein, the protective material is to prevent reaction between the liquid coolant and the cold plate's material, the cooling system comprising pumping equipment and cooling equipment fluidically coupled downstream from the cold plate to receive warmed liquid coolant from the cold plate, the cold plate fluidically coupled downstream from the pumping equipment and cooling equipment to received cooled liquid coolant.

10. The computing system of claim 9 wherein the cold plate comprises a base and a cover that are brazed together.

11. The computing system of claim 10 wherein a bonding material between the base and the cover has a melting point temperature that is less than a temperature at which the protective material will delaminate from the cold plate's material.

12. The computing system of claim 9 wherein the cold plate material comprises copper.

13. The computing system of claim 12 wherein the protective material comprises nickel.

14. The computing system of claim 9 wherein the protective material is plated on the cold plate's material.

15. The computing system of claim 9 wherein the protective material is coated on the cold plate's material.

16. The computing system of claim 9 wherein the protective material is at least one of:
a sealant;
an epoxy.

17. A method, comprising:
depositing a protective material on a surface area of a cold plate component, the surface area to form one or more fluidic channels within a cold plate to be formed with the cold plate component, a liquid coolant to flow through the fluidic channels; and,
forming the cold plate by attaching the cold plate component to another cold plate component by melting a bonding material between the cold plate component and the another cold plate component, wherein, the bonding material has a melting point temperature that is less than a temperature at which the protective material will delaminate from the cold plate component.

18. The method of claim 17 wherein the cold plate component comprises copper.

19. The method of claim 18 wherein the protective material comprises nickel.

20. An apparatus, comprising:
a cold plate, the cold plate having a protective material on the cold plate's outer surface such that when the cold plate is immersed in liquid coolant of an immersion cooling system, the protective material is between the liquid coolant and the cold plate's material, wherein, the protective material is to prevent reaction between the liquid coolant and the cold plate's material.
